(19) United States
(12) Patent Application Publication
(10) Pub. No.: US 2002/0106460 A1
(43) Pub. Date: Aug. 8, 2002

(54) Low dielectric constant fluorocarbonated silicon films for integrated circuits and method of preparation

(76) Inventors: Gil Sik Lee, Baton Rouge, LA (US); Yoonyoung Jin, Baton Rouge, LA (US); Kihong Kim, Torrance, CA (US)

Correspondence Address: PATENT DEPARTMENT, TAYLOR, PORTER, BROOKS & PHILLIPS, L.L.P, P.O. BOX 2471, BATON ROUGE, LA, 70821-2471, US

(21) Appl. No.: 09/778,489

(22) Filed: Feb. 7, 2001

(51) Int. Cl. C23C 16/00

(52) U.S. Cl. 427/569; 427/255.39

(57) ABSTRACT

Fluorocarbonated silicon films having very low dielectric constants, and a method for fabricating those films are disclosed. The low dielectric constants of the novel films make them suitable for use in ULSI fabrication techniques. The novel films may be prepared using a SiH₄ or Si₂H₆ precursor as a silicon source, and CF₄, C₂F₆, or C₄F₈ as a source of carbon and fluorine. The films not only have low dielectric constants (typically, k=1.9 to 2.3), they also exhibit high dielectric breakdown voltages. The process may be carried out at relatively low temperatures. The novel films may readily be used with conventional etching techniques, and they adhere well.

This invention pertains to insulators of low dielectric constant that are useful, for example, in semiconductor devices, particularly to novel fluorocarbonated silicon (SiCF) films and their method of preparation.

The development of low dielectric constant (low-k) materials for use as interlayer dielectrics has become a key challenge in the development of high performance ultra-large-scale-integration (ULSI) devices. The decreased design dimensions and the increased complexity of ULSI circuits will greatly increase the crosstalk and RC time delay caused by parasitic capacitance. To reduce these problems, much effort has been spent in reducing the dielectric constant of the interlayer.

Several choices of low-k materials have been investigated, including fluorinated SiO₂, fluorinated carbon, diamond-like carbon, fluorinated polyimide, Teflon-type fluoropolymers, aerogels, and even air gaps. Any chosen low-k material has to meet stringent electrical, mechanical, chemical, and thermal requirements. However, none of the low-k candidates just mentioned satisfies all these requirements.

In current VLSI (very large scale integration) fabrication techniques, inter-metal dielectric materials having a k value in the range 3.9-5.0 are typically used. This range of dielectric constant is too high for future generations of ULSI (ultra large scale integration) fabrication. It is generally accepted in the industry that dielectrics with k values in the range 3.0-4.0 will be needed for circuits having 0.18 μm features, and that k values in the range 2.5-3.0 will be needed for 0.15 or 0.13 μm features. Several materials, such as fluorinated silicon oxide and fluoropolymers, have been proposed as candidates for low-k dielectrics in ULSI fabrication. Organic films with k=2.1 are being developed, but they have several disadvantages such as the need for hard masks for etching and the problem of adhesion.

However, most fluorinated silicon oxides do not have k values sufficiently low for circuits with 0.15 or 0.13 μm features. Although fluoropolymers such as PTFE (poly tetrafluoroethylene) do exist with k values in the range 1.9-2.1, the use of these fluoropolymers has been hindered by their generally poor adhesion and poor thermal stability.

Plasma-enhanced chemical vapor deposition (PECVD) has been widely used in integrated circuit technology to deposit silicon dioxide (SiO₂) films at lower-temperatures. In the PECVD process, a radio frequency (rf) glow discharge supplies part of the energy to promote a desired chemical reaction.

U.S. Pat. No. 5,789,819 discloses semiconductor devices containing open-pored dielectric layers, formed by an aerogel process.

U.S. Pat. No. 5,660,895 discloses the deposition of high-quality SiO₂ films at low temperatures by plasma-enhanced chemical vapor deposition using disilane and nitrous oxide or elemental oxygen as silicon and oxygen precursors. Optionally, fluorinated silicon oxide could also be deposited at the relatively low temperature of 120° C. via plasma-enhanced chemical vapor deposition by also adding a fluorine source such as tetrafluoromethane to the deposition process. The k value of the films produced by this process is ˜4.6. These films contain essentially no carbon.

L. Peters, “Pursuing the perfect low-k dielectric,” Semiconductor International, vol. 21, No. 10, pp. 64-74, (September 1998) gives an overview of recent efforts to develop low dielectric constant materials for use in semiconductor chips. This paper mentions concerns with fluorine-containing films, e.g., evolution of fluorine from the film, resulting in etching of other components.

T. Usami et al, “Low dielectric constant interlayer using fluorine-doped silicon oxide,” Jpn. J. Appl. Phys., vol. 33, pp. 408-412 (1994) discloses a fluorine-doped silicon oxide film formed by adding hexafluoroethane to conventional tetraethoxysilane-based plasma-enhanced chemical vapor deposition.

R. Sharangpani et al., “Chemical vapor deposition and characterization of amorphous Teflon fluoropolymer thin films,” J. Electron. Mater., vol. 26, pp. 402-409 (1997) discloses the chemical vapor deposition of the copolymeric amorphous Teflon fluoropolymer AF 1600, and reported that the resulting film had a k-value of about 1.93.

Teflon-type (fluoropolymer) materials have adhesion problems, and are also difficult to etch because they are so stable.

M. Shapiro et al., “CVD of fluorosilicate glass for ULSI applications,” Thin Solid Films, vol. 270, pp. 503-507 (1995) reviews the use of fluorine in SiO₂ films in a CVD process to lower the dielectric constant. One example mentioned used CF₄ as the fluorine source, and SiH₄ as the silicon source, in a reaction conducted at 400° C.

B. Fowler et al., “Relationships between the material properties of silicon oxide films deposited by electron cyclotron resonance chemical vapor deposition and their use as an indicator of the dielectric constant,” J. Vac. Sci. Technol. B, vol. 12, pp. 441-449 (1994) discloses the plasma-enhanced chemical vapor deposition of thin films from a gas mixture of Ar, O₂, and SiH₄, and mentions that the dielectric constant was correlated with the Si—OH content of the resulting film.

There is an unfilled need for low-k dielectrics that will be suitable for ULSI fabrication, using the existing tool set.

We have discovered novel fluorocarbonated silicon films having very low dielectric constants, and a novel method for fabricating those films. The low dielectric constants of the novel films make them suitable for use in ULSI fabrication techniques, using the existing tool set for semiconductor chip manufacture, as well as methods for manufacturing the new dielectric materials. The novel films may be prepared using a SiH₄ or Si₂H₆. precursor as a silicon source, and CF₄, C₂F₆, or C₄F₈ or other precursor as a source of carbon and fluorine. The films not only have low dielectric constants (typically, k=1.9 to 2.3), they also exhibit high dielectric breakdown voltages. Although the process may be conducted at higher temperatures, such as 350° C. or 250° C. , surprisingly, the process may be carried out quite successfully at substantially lower temperatures: 210° C., 180° C., 150° C., 120° C., 90°C., 60° C., 30° C., or even lower. The optimal temperature will depend on the specific substrate used.

The process produces high-quality dielectric materials with a high dielectric breakdown strength, and requires only two precursor materials. The process may be carried out at low temperatures. The films may be used for semiconductor chip interlayers, or for the back end of the line interconnect structures of ultra large scale integrated (ULSI) devices. The films may also be used in microelectromechanical systems, e.g., as sacrificial layers, for passivation on compound semiconductors, or in mask layers in multilevel lithography. The C:F ratio may be adjusted if desired, simply by changing the concentrations of the precursors. The sources themselves need not be altered.

The novel films may readily be used with conventional etching techniques, and they adhere well.

The novel films have a high carbon level, typically ˜60%, although higher and lower carbon levels are also possible. The other principal constituents are silicon and fluorine.

### BRIEF DESCRIPTION OF THE DRAWINGS

FIG. 1 depicts the deposition rate and refractive index of an SiCF film as a function of rf power.

FIG. 2 depicts the deposition rate of an SiCF film as a function of the flow rate ratio of CF₄ to Si₂H₆.

FIG. 3 depicts the dielectric constant of an SiCF film as a function of the flow rate ratio of CF₄ to Si₂H₆.

FIG. 4 depicts typical J-E characteristics of MOS capacitors fabricated using an SiCF film fabricated at various flow rate ratio of CF₄ to Si₂H₆.

A preferred technique for preparing the novel SiCF films is plasma-enhanced chemical vapor deposition (PECVD). Preferred ranges for rf power, chamber pressure, and substrate temperature are in the range of 50-300 W, 400-1000 mTorr, and 25-300° C., respectively. Most preferred process conditions in terms were 200 W, 180° C., and 700 mTorr for rf power, deposition temperature, and chamber pressure, respectively, and 16.5 for the flow rate ratio of CF₄ to Si₂H₆.

In each of the Examples described below, except as otherwise mentioned in the context of a particular Example, the process parameters and measurements were as follow: The films were deposited using a Plasma Therm PECVD system (model VII-70) (St. Petersburg, Fla.), which has a parallel electrodes with a spacing of 2.54 cm and a diameter of 25.4 cm. Boron-doped silicon (100) wafers with resistivity of 5-15 Ω-cm were used as the substrates, and were cleaned according to the standard RCA cleaning procedure. The substrate temperature and the chamber pressure were maintained at 180° C. and 700 mTorr, respectively during deposition. In some cases, the deposition flow rate ratio of CF₄/Si₂H₀. was varied between 13 and 18, while maintaining the total flow rate of Si₂H₆ (5% in He) and CF₄ at 73 sccm (“standard cc per minute”). In some cases, the rf power was varied from 50 to 300 W. The thickness of the films was measured using the Applied Materials Ellipsometer model (Santa Clara, Calif.). Metal oxide-semiconductor (MOS) capacitors, with gate areas of 2.46×10⁻³ cm² each, were fabricated by standard photolithography techniques, with aluminum was used for the metal contacts. High frequency C-V measurements were performed with an HP 4275A LCR meter (Santa Clara, Calif.) by superimposing a 25 mV ac signal at 1 MHz onto a dc voltage with a sweep rate of 20 mV/s. The I-V measurements were performed with an HP4140 voltage source (Santa Clara, Calif.) and a Keithley 485 Picoammeter (Cleveland, Ohio). All measurements performed subsequent to the deposition of the films were conducted on the as-deposited films at room temperature.

Pre-deposition cleaning was performed with the conventional RCA two-step cleaning procedure. In the first step, the wafers were exposed for 5 minutes at 70° C. to a 5:1:1 solution of deionized water: 30% hydrogen peroxide solution: 30% ammonium hydroxide solution. The first step removed any organic surface films, and exposed the surface for decontamination reactions. In the second step, the rinsed wafers from the first step were exposed for 5 minutes at 70° C. to a 6:1:1 solution of deionized water: 30% hydrogen peroxide solution: 37% hydrochloric acid solution. The second step removed metallic contaminants that were not removed during the first step.

In some cases the RCA cleaning was followed by dipping in a dilute hydrofluoric acid solution containing 100 parts deionized water to 1 part of 48% HF solution.

Post-deposition annealing processes, where performed, were carried out in a conventional tube furnace flowing N₂ for 30 minutes.

### EXAMPLE 1

An SiCF film was deposited using Si₂H₆ and CF₄ as precursors, using parallel plate PECVD deposition. The process conditions were as follows:

Flow rate of Si₂H₆ (5% in He carrier)=40 sccm

Flow rate of CF₄=33 sccm

Deposition temperature=180° C.

Chamber pressure=700 mTorr

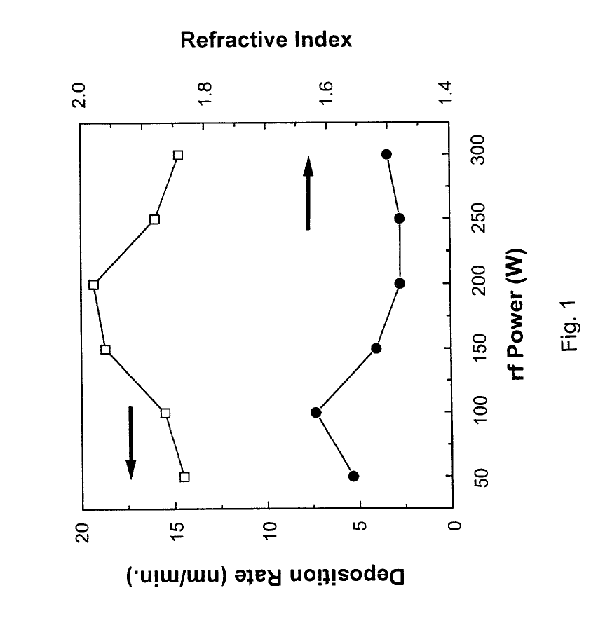

FIG. 1 depicts the deposition rate and refractive index of the film as a function of rf power under these process conditions.

The rf power is an important parameter affecting the deposition, since it controls the degree of dissociation of the precursors. The deposition rate of the film at an rf power of 50 W was observed to be 14.5 nm/min. As the rf power increased to 200 W, the deposition rate increased about 30%. The deposition rate then decreased as rf power increased to 250 and 300 W.

Without wishing to be bound by this theory, we believe that these observations may be explained by the following mechanisms. Increasing the rf power dissociated a greater fraction of the precursors, producing higher concentrations of radicals that are then available for film deposition. However, as the rf power increased further, higher etching rates began to reduce the overall rate of deposition.

The refractive index of the film was lowest at an rf power of about 200 W, probably because the amount of fluorine incorporated into the film was highest at this power.

In view of the maximum deposition rate and minimum refractive index, the most preferred rf power was about 200 W.

### EXAMPLE 2

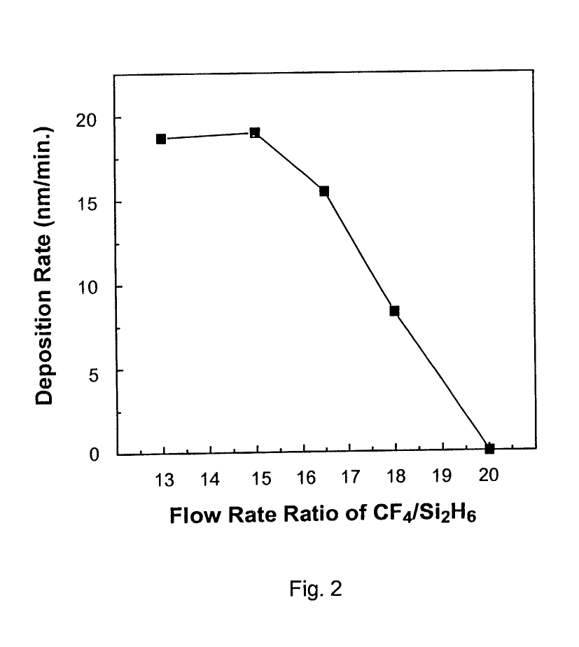

Process conditions were as stated above, except that the rf power was fixed at 200 W, the total flow rate of the combined CF₄ and Si₂H₆ precursors was fixed at 73 sccm, and the flow rate ratio of CF₄ to Si₂H₆ was varied. As shown in FIG. 2, above a CF₄ to Si₂H₆ ratio greater than about 15, the deposition rate decreased as the ratio of CF₄ to Si₂H₆ increased. When this ratio reached 20, essentially no film deposition was observed, suggesting that fluorine-promoted etching dominated over deposition.

### EXAMPLE 3

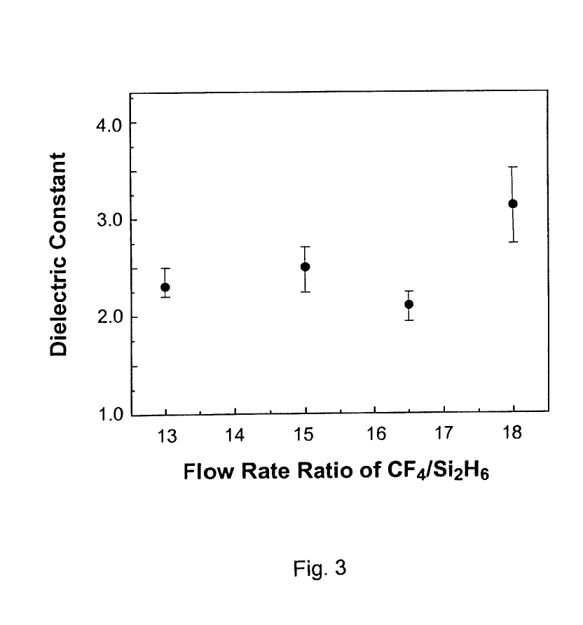

Process conditions were as stated above. FIG. 3 depicts the dielectric constant of the resulting SiCF film as a function of flow rate ratio of CF₄ to Si₂H₆.

The average thickness of the film measured at various flow rate ratios was 1120 Å (at 13), 1140 Å (at 15), 930 Å (at 16.5) and 600 Å (at 18).

The dielectric constant (k) was calculated from the relation k=TₒₓCₒₓ/∈ₒ, where Tₒₓ=oxide thickness, Cₒₓ=oxide capacitance per unit area, and ∈ₒ=permittivity of vacuum.

The lowest dielectric constant of 1.9 was obtained at a flow rate ratio, CF₄ to Si₂H₆, of 16.5.

### EXAMPLE 4

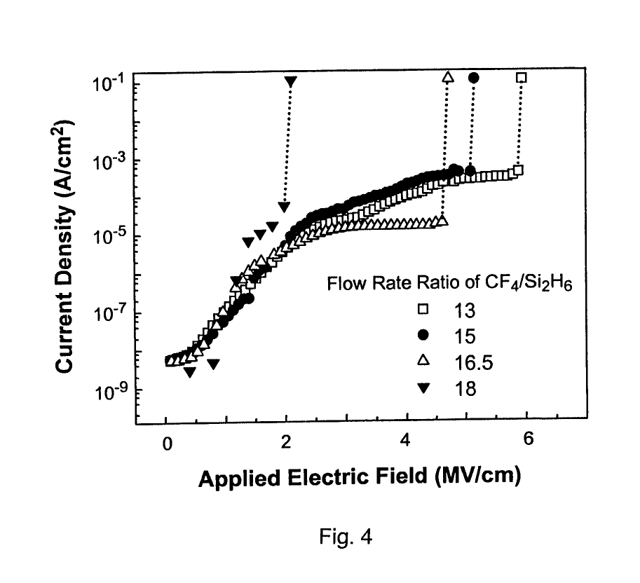

Process conditions were as stated above. FIG. 4 depicts typical J-E characteristics (current density versus applied electric field) of MOS capacitors fabricated from the novel SiCF film as a function of flow rate ratio of CF₄ to Si₂H₆.

This measurement was conducted at room temperature by applying a negative bias (ramp rate=1 V/sec) to the gate area to cause electron injection. We observed that the leakage current at “trapping ledge” was lowest for the flow rate ratio, CF₄ to Si₂H₆, of 16.5.

The average breakdown field strength observed was 4.74 MV/cm.

### Miscellaneous

Fluorine/carbon precursors that may be used in the present invention include not only the more common precursors carbon tetrafluoride, perfluoroethane, and perfluorocyclobutane; but also other sources of carbon and fluorine atoms, including by way of example, octofluorocyclobutane, perfluorobutane, perfluorotoluene, perfluoromethylcyclohexane, perfluoro-n-heptane, perfluoronaphthalene, 1,4-difluorobenzene, and others known in the art. Such carbon/fluorine precursors are available from a number of commercial gas supply sources.

The complete disclosures of all references cited in this specification are hereby incorporated by reference. Also incorporated by reference is the full disclosure of the following unpublished manuscript (including its figures): Y. Jin et al., “Preparation of low dielectric constant silicon containing fluorocarbon films by plasma enhanced chemical vapor deposition,” to appear in J. Vac. Sci. Tech. (2001). In the event of an otherwise irreconcilable conflict, however, the present specification shall control.

We claim:

1. A process for depositing a fluorocarbonated silicon film onto a substrate, said process comprising the steps of:
(a) exposing the substrate to a mixture of disilane and a precursor of fluorine and carbon atoms; at a temperature below about 350° C.; and
(b) creating a plasma in the mixture with a radio frequency discharge or with electron cyclotron resonance, wherein the temperature of the mixture remains below about 350° C, and continuing for a time sufficient to deposit a fluorocarbonated silicon film from the plasma onto the substrate.

2. A fluorocarbonated silicon film produced by the process of claim 1.

3. A process as recited in claim 1, wherein the fluorocarbonated silicon film produced by the process has a k value of about 2.0 or below.

4. A fluorocarbonated silicon film produced by the process of claim 3.

5. A process as recited in claim 1, wherein the temperature of the mixture remains below about 250° C. during said exposing and creating steps.

6. A fluorocarbonated silicon film produced by the process of claim 5.

7. A process as recited in claim 5, wherein the fluorocarbonated silicon film produced by the process has a k value of about 2.0 or below.

8. A fluorocarbonated silicon film produced by the process of claim 7.

9. A process as recited in claim 1, wherein the temperature of the mixture remains below about 180° C. during said exposing and creating steps.

10. A fluorocarbonated silicon film produced by the process of claim 9.

11. A process as recited in claim 9, wherein the fluorocarbonated silicon film produced by the process has a k value of about 2.0 or below.

12. A fluorocarbonated silicon film produced by the process of claim 11.

13. A process as recited in claim 1, wherein the temperature of the mixture remains below about 150° C. during said exposing and creating steps.

14. A fluorocarbonated silicon film produced by the process of claim 13.

15. A process as recited in claim 13, wherein the fluorocarbonated silicon film produced by the process has a k value of about 2.0 or below.

16. A fluorocarbonated silicon film produced by the process of claim 15.

17. A process as recited in claim 1, wherein the temperature of the mixture remains below about 120° C. during said exposing and creating steps.

18. A fluorocarbonated silicon film produced by the process of claim 17.

19. A process as recited in claim 17, wherein the fluorocarbonated silicon film produced by the process has a k value of about 2.0 or below.

20. A fluorocarbonated silicon film produced by the process of claim 19.

21. A process as recited in claim 1, wherein the temperature of the mixture remains below about 90° C. during said exposing and creating steps.

22. A fluorocarbonated silicon film produced by the process of claim 21.

23. A process as recited in claim 21, wherein the fluorocarbonated silicon film produced by the process has a k value of about 2.0 or below.

24. A fluorocarbonated silicon film produced by the process of claim 23.

25. A process as recited in claim 1, wherein the temperature of the mixture remains below about 60° C. during said exposing and creating steps.

26. A fluorocarbonated silicon film produced by the process of claim 25.

27. A process as recited in claim 25, wherein the fluorocarbonated silicon film produced by the process has a k value of about 2.0 or below.

28. A fluorocarbonated silicon film produced by the process of claim 27.

29. A process as recited in claim 1, wherein the temperature of the mixture remains below about 30° C. during said exposing and creating steps.

30. A fluorocarbonated silicon film produced by the process of claim 29.

31. A process as recited in claim 29, wherein the fluorocarbonated silicon film produced by the process has a k value of about 2.0 or below.

32. A fluorocarbonated silicon film produced by the process of claim 31.

33. A process as recited in claim 1, wherein the fluorine and carbon precursor comprises CF₄, and wherein the ratio of CF₄ to disilane is between about 10 and about 20.

34. A fluorocarbonated silicon film produced by the process of claim 33.
